(19) United States
(12) Patent Application Publication
(10) Pub. No.: US 2006/0172068 A1
(43) Pub. Date: Aug. 3, 2006

(54) Deposition of multilayer structures including layers of germanium and/or germanium alloys

(76) Inventor: Stanford R. Ovshinsky, Bloomfield Hills, MI (US)

Correspondence Address: ENERGY CONVERSION DEVICES, INC., 2956 WATERVIEW DRIVE, ROCHESTER HILLS, MI, 48309, US

(21) Appl. No.: 11/244,929

(22) Filed: Aug. 1, 2005

Related U.S. Application Data
(63) Continuation-in-part of application No. 11/046,114, filed on Jan. 28, 2005.

(51) Int. Cl. C23C 16/00; B05D 1/36

(52) U.S. Cl. 427/248.1; 427/402

(57) ABSTRACT

A chemical vapor deposition (CVD) process for preparing multilayer structures including Ge or a Ge-containing layer for use in electrical, optical and photovoltaic applications. A preferred Ge precursor is isobutylgermane. The multilayer structures include structures having a layer of Ge formed from isobutylgermane and structures having a layer of SiGe where isobutylgermane is used as a Ge precursor. The instant invention generally includes multilayer structures that include a layer of Ge or a layer of SiGe in combination with a layer of Si. Embodiments include multilayer structures having two or more layers containing an alloy of Si and Ge, where the Si:Ge differs in the two or more layers.

### CROSS-REFERENCE TO RELATED APPLICATIONS

This application is a continuation-in-part of application Ser. No. 11/046,114, filed Jan. 28, 2005, entitled “Chemical Vapor Deposition of Chalcogenide Materials”, the disclosure of which is herein incorporated by reference.

### FIELD OF INVENTION

This invention relates to a process for preparing photovoltaic devices containing germanium. More particularly, this invention relates to the formation of graded bandgap device structures containing layers germanium and germanium alloys.

### BACKGROUND OF THE INVENTION

Germanium is a common element in many technologically relevant materials. It is widely used in the semiconductor industry in electronic devices in pure form or in alloy form, especially SiₓGe₁₋ₓ. Since Ge has a lower bandgap than Si, alloys of Si with Ge provide for continuous tenability of bandgap and this feature is useful in applications such as photovoltaic devices and solar cells where it is desired to fabricate structures containing multiple layers with different bandgaps to absorb different portions of the solar spectrum. Ge and Ge alloys are also commonly used in electronic devices such as diodes and transistors.

In co-pending U.S. patent application Ser. No. 11/046,114 ('114 application), the instant inventors described the use of an alkylgermanium precursor for the deposition of Ge-containing materials. Of particular interest in the '114 application was the vapor phase deposition of chalcogenide materials containing Se and/or Te along with Ge for use in electrical and optical materials. The Ge precursor of the '114 application enabled the vapor phase deposition of Ge as well as binary, ternary and higher alloys of Ge with chalcogen elements. The precursor isobutylgermane ((i-butyl)GeH₃) was shown to have especially favorable decomposition characteristics and enabled the vapor phase deposition of Ge and Ge-containing materials at lower temperatures in thermal vapor deposition processes than was possible with germane (GeH₄), presently the most widely used germanium precursor.

Given the promising deposition characteristics of the alkylgermane precursors, it is desirable to extend their use to new alloys of Ge, to new Ge-containing materials, and to combinations of the foregoing with other materials and alloys.

### SUMMARY OF THE INVENTION

This invention provides a process for the deposition of Ge-containing materials and multilayer structures that include Ge or a Ge-containing layer. The instant process is a vapor phase deposition process that permits thermal deposition and/or plasma enhanced deposition of Ge precursors alone or in combination with other precursors.

In one embodiment a Ge is deposited on an Si wafer. In another embodiment, layers of Ge are deposited on layers of Si to form multilayer structures that include two or more alternating layers. In another embodiment, layers of SiGe are formed. In still another embodiment, graded layers of Si₁₋ₓGeₓ are formed. In yet another embodiment, a layer of SiₓGe₁₋ₓ is formed in combination with a layer of Ge.

The preferred Ge precursors are Ge precursors derived from germane through substitution of one or more hydrogen groups with an organic group. Organic groups including alkyls, alkenyls, alkynyls, and aryls. An especially preferred precursor is isobutylgermane. The preferred Ge precursors may be reacted alone to form a Ge layer or in combination with silane or other silicon precursors to form SiGe.

### DETAILED DESCRIPTION OF THE ILLUSTRATED EMBODIMENTS

The instant invention demonstrates the vapor deposition synthesis of optical and electrical materials containing Ge in thin film form. As used herein, vapor phase deposition encompasses all variations of vapor deposition including those generally referred to in the art as VPE, MOVPE, MOCVD, OMVPE, OMCVD, PECVD and RPCVD.

In a preferred embodiment of the instant invention, a Ge precursor is combined with one or more additional precursors in a CVD process to produce solid phase Ge-containing materials containing two or more elements. The CVD deposition occurs in a CVD reactor or chamber. The CVD reactor includes a substrate onto which deposition occurs. The substrate can be a stationary substrate (e.g. a wafer) or a moving substrate (e.g. continuous web). The substrate can be lattice-matched to the CVD-deposited thin film or not. Growth precursors for the deposition are introduced into the CVD reactor and the reaction is commenced. During deposition, the reactor pressure and temperature are adjusted to optimize the deposition rate and purity of the thin film that is formed. Depending on the composition, substrate, reactor conditions, precursors etc. the thin film formed can be epitaxial, crystalline, polycrystalline, amorphous, homogeneous, heterogeneous etc.

Two CVD processing strategies are employed in the instant invention. In one embodiment, the instant chalcogenides are prepared through a direct CVD process, in which precursors for each element to be included in the ultimate thin film material are introduced simultaneously into a CVD reactor to form a multi-element chalcogenide material. In another embodiment, the instant chalcogenides are prepared through an alternating CVD process in which a penultimate multilayer structure is deposited, where each of the alternately deposited layers includes a different subset of the elements to be included in the intended ultimate composition and a post-CVD processing step is used to induce a transformation of the penultimate multilayer structure into the ultimate film.

Successful CVD synthesis of multiple element materials requires careful design of the precursor species. The CVD reaction is a gas phase reaction of precursors. It is therefore necessary to utilize gas phase precursors directly or to transform liquid and solid phase precursors into the gas phase prior to reaction. An important attribute of a precursor is the ability to introduce it at a steady and reproducible rate during the CVD reaction. Gas phase precursors are convenient for this purpose since they can be released and delivered to the reactor at a constant flow rate with a high degree of reproducibility. Oftentimes, gas phase precursors are diluted in a carrier gas such as He or Ar to control concentration in the reactor. Liquid and solid phase CVD precursors are also suitable, but require pre-delivery vaporization or sublimation prior to introduction into the CVD reactor. Vaporization or sublimation can be accomplished thermally or through entrainment in a carrier gas. Bubblers, for example, often used to deliver liquid phase precursors to CVD reactors. Solid phase precursors are often the most problematic in terms of achieving uniform precursor delivery rates because the surface area of a solid varies over the course of a deposition run. Mass flow controllers can be used to insure uniform delivery of vaporized or sublimed precursors into the CVD reactor.

Once the precursor is introduced into the CVD reactor, it reacts with other precursors to form a thin film. The reaction can occur through a gas phase reaction followed by deposition onto the substrate surface. Alternatively, the precursors can be decomposed (e.g. thermally or through plasma excitation) into reactive intermediate species (frequently including free radical species) that can combine in the gas phase or on the surface of the substrate to form the desired thin film. Many CVD reactions occur through decomposition of one or more precursors into reactive intermediate species that adsorb onto the substrate surface. Once on the surface, reactive species formed from different precursors react to form a multielement thin film.

When binary or multi-element materials as ultimate thin films or layers within a multilayer penultimate structure are to be prepared, two or more precursors are introduced simultaneously into the CVD reactor. The complexity of the process increases due to the need to insure comparable rates of reaction or decomposition of the different precursors in the gas phase reaction environment of the reactor. When a multi-element material is prepared, it is beneficial for the precursors to provide the necessary elements at similar rates so that more nearly uniform and homogeneous thin films are formed. If one precursor reacts at a significantly faster rate than other precursors, the possibility arises that a film of non-uniform or undesired composition forms. A faster reacting precursor, for example, may deposit a mono-elemental layer onto the substrate before appreciable reaction or decomposition of slower reacting precursors has occurred. As a result, the stoichiometric ratio desired in the deposited material may be lacking. In the case of ternary and higher compositions, preferential reactions between a subset of the precursors may also occur and lead to the formation of a thin film that is depleted with respect to the element(s) of the non-preferentially reacting precursor(s). A further complication arises if the elements (or reactive species containing the elements) desired in the deposited film differ appreciably in volatility. Volatility is a relevant consideration because surface desorption of the desired elements (or species containing the desired elements) can occur during CVD deposition. If the different elements of a multi-element composition desorb at appreciably different rates from the surface, the intended stoichiometry may not be achieved.

The CVD preparation of multi-element compositions therefore requires careful selection of precursors and reaction conditions. The reactivity of CVD precursors is influenced by the conditions in the reactor (e.g. temperature, pressure, and concentration) as well as by the chemical features of the precursor itself. The conditions within the reactor can be varied to optimize the quality of deposited thin films for a given combination of precursors and the individual precursors can be optimized with respect to their intrinsic reactivity through control of the structure and bonding of the precursor. Most precursors include a central element or elements that one wishes to incorporate into a CVD thin film along with peripheral elements or groups that are bonded to the central element or elements. Many precursors, for example, include a central metal or non-metal atom that is bonded by one or more ligands that decompose in the CVD deposition during the formation of the reactive intermediate that contains the central element. The bond strength between such ligands and the central atom is typically an important contributing factor in the rate of reaction or decomposition of the precursor. Through judicious control of the ligands or other substituents, the reactivity of a precursor with respect to the delivery of elements desired in the deposited thin film can be controlled through control of relevant factors such as decomposition rate, reaction rate and desorption rate. Chemical tuning of the properties of CVD precursors is an important degree of freedom in multi-element depositions. Such chemical tuning can be used to identify and optimize combinations of precursors to improve the quality of multi-element films and to minimize incorporation of impurity elements into the deposited film.

The instant invention focuses on the CVD synthesis of Ge-containing materials in thin film form. In a preferred embodiment, the material is an optical or electrical material containing multiple layers that include a Ge layer or an SiₓGe₁₋ₓ layer. SiₓGe₁₋ₓ may be referred herein as SiGe, where it is understood that the full range of alloy compositions is intended. In one embodiment, the multilayer structure includes a layer of Ge deposited on a layer of Si (or vice versa). In another embodiment, the multilayer structure includes a layer of Ge deposited on a layer of SiGe (or vice versa). In still another embodiment, the multilayer structure includes a layer of SiGe deposited on a layer of Si. Other embodiments include multilayer structures that include three or more layers, including superlattice structures, in which layers of Si, Ge and SiGe are included and arranged in any order relative to each other.

The preferred Ge precursors are substituted germane precursors having the general formula RₓGeH₄₋ₓ, where R is an organic group such as an alkyl, alkenyl, alkynyl or aryl group. Examples of the preferred Ge precursors are described in the '114 application and in U.S. Pat. Appl. Pub. Nos. 20040198042 and 20040197945, the disclosures of which are incorporated by reference herein. The preferred Si precursor is silane (SiH₄), a substituted silane RₓSiH₄₋ₓ, or disilane.

### EXAMPLE 1

In this example, the CVD synthesis of Sb₂Te₃ on a silicon nitride substrate is demonstrated. The CVD reactor includes a substrate mount, multiple precursor inlets for delivering precursors in vapor or gas phase form directly or diluted in a carrier gas as well as separate overhead showerhead and backfill lines for providing background pressure of an inert ambient gas.

A silicon nitride wafer substrate was placed in a CVD reaction chamber. Tris(dimethylamino)antimony (Sb(N(CH₃)₂)₃)was used as the antimony (Sb) precursor to provide the Sb necessary for film formation. Diisopropyltellurium (Te(CH(CH₃)₂)₂) was used as the tellurium (Te) precursor to provide the Te necessary for film formation. Both precursors are liquids at ambient condition and were delivered to the CVD reactor in a vapor phase form through use of a bubbler. The Sb-precursor and the Te-precursor were placed in separate bubblers connected through separate lines to the CVD reactor. Each bubbler and its delivery lines were heated to 75° C. N₂ was used as a carrier gas for delivering each of the precursors to the CVD reactor. N₂ was bubbled through each bubbler at a flow rate of 300 sccm to produce a gas stream containing each precursor in a vapor phase form diluted in N₂, which serves as a carrier gas. Each of these gas streams was further diluted in another 200 sccm of N₂ and then introduced into the CVD reactor to undergo a film formation reaction. During the deposition, 250 sccm of N₂ was delivered from the showerhead from above the substrate and 250 sccm of N₂ was delivered from below the substrate through the backfill line. The total pressure in the CVD reactor during deposition was approximately 3 Torr.

The substrate was heated to 350° C. and was rotated at 50 rpm during the CVD reaction. Rotation of the substrate promotes uniformity of deposition across the substrate. The reaction was permitted to run for ˜30 minutes and on conclusion of the reaction, a film of about 3000 Å in thickness had been prepared on the substrate.

The film was analyzed using Auger emission spectroscopy. The Auger analysis confirmed the presence of Sb and Te in the deposited film and further showed that the Sb:Te atomic ratio was approximately 36:56 or 2:3.1, which is in agreement with the expected ratio for Sb₂Te₃. The depth profiling further shows the uniformity of the composition of the film in the thickness direction. This indicates that a uniform binary film was deposited instead of separate layers or regions of Sb and Te. A scanning electron micrograph of a portion of the deposited film obtained at a magnification of 4000× indicated that the deposited film is polycrystalline in nature. A typical grain size in the film is on the order of microns.

### EXAMPLE 2

In this example, a two layer structure including solid phase layers of Sb₂Te₃ and Ge is prepared in a CVD process. The deposition was performed on a SiN substrate that was rotated at 50 rpm. The CVD reactor, the Sb-precursor and Te-precursor used in this example are as described in EXAMPLE 1 hereinabove. The Ge-precursor was isobutylgermane, H₃Ge(i-C₄H₉). The Ge-precursor is a high vapor pressure liquid at ambient conditions and was delivered to the CVD reactor through a bubbler.

The deposition began with deposition of a Ge layer. The Ge-precursor was placed in a bubbler. 200 sccm of He was bubbled through the Ge-precursor to provide a gas stream containing the Ge-precursor in a vapor phase form in He as a carrier gas. This gas stream was further diluted with 300 sccm of He and then injected into the reactor. During deposition of the Ge layer, 400 sccm He was injected through the showerhead and 250 sccm He was injected through the backfill line. The reactor pressure during deposition of the Ge layer was approximately 6 Torr and the substrate temperature was approximately 400° C. The deposition was allowed to proceed for 15 minutes and was then terminated. The reactor was purged without removing the substrate containing the Ge layer and readied for deposition of an Sb₂Te₃ layer.

The Sb₂Te₃ layer was deposited directly onto the Ge layer under conditions as described in EXAMPLE 1 hereinabove. The deposition was permitted to run for 25 minutes and then terminated.

This example demonstrates the deposition of a multilayer structure containing two layers, one of which contains Ge.

### EXAMPLE 3

In this example, a single layer three-element solid phase chalcogenide thin film is deposited by chemical vapor deposition. The deposition was performed on a SiN substrate that was rotated at 50 rpm. The CVD reactor, the Sb-precursor, Te-precursor and Ge-precursor used in this example are as described in EXAMPLE 1 and EXAMPLE 2 hereinabove.

The deposition in this example was accomplished through a reaction of the Sb-precursor, Te-precursor, and Ge-precursor, where all three precursors were present simultaneously in the CVD reactor. The precursors were introduced into the CVD reactor through separate feed lines. Helium (He) was used as a carrier gas for all three precursors. The Sb-precursor and Te-precursor were placed in separate bubblers heated to 75° C. and delivered to the CVD reactor through separate feed lines, also heated to 75° C. He was bubbled through the Sb-precursor bubbler at a flow rate of 200 sccm to produce a gas stream containing the Sb-precursor in a vapor phase form diluted in He, which serves as a carrier gas. This gas stream was further diluted in another 100 sccm of He and then introduced into the CVD reactor to provide the Sb-precursor in a vapor phase form to the film formation reaction. He was bubbled through the Te-precursor bubbler at a flow rate of 200 sccm to produce a gas stream containing the Te-precursor in a vapor phase form diluted in He, which serves as a carrier gas. This gas stream was further diluted in another 100 sccm of He and then introduced into the CVD reactor to provide the Te-precursor in a vapor phase form to the film formation reaction. The Ge-precursor was placed in a separate bubbler. 200 sccm of He was bubbled through the Ge-precursor bubbler to provide a gas stream containing the Ge-precursor in a vapor phase form in He as a carrier gas. This gas stream was further diluted with 300 sccm of He and then injected into the CVD reactor to provide the Ge-precursor in a vapor phase form to the film formation reaction.

During the deposition, 400 sccm of He was delivered from the showerhead from above the substrate and 250 sccm of He was delivered from below the substrate through the backfill line. The total pressure in the CVD reactor during deposition was approximately 6 Torr. The substrate was heated to 400° C. during the CVD reaction. The reaction was permitted to run for ˜15 minutes and on conclusion of the reaction, a film of about 3000 Å in thickness had been prepared on the substrate.

A scanning electron microscopy analysis of the film was completed and showed several larger crystallites in the presence of a finer grain background material. Elemental analysis of the background material and crystallites were completed using EDS. The EDS results indicated that the ratio of Ge:Sb:Te in the background material was 1:2:3, thus indicating a stoichiometric GeSb₂Te₃ composition. The EDS results indicated that the ratio of Ge:Sb:Te in the crystallites was 2:2:5, thus indicating a stoichiometric Ge₂Sb₂Te₅ composition.

The film was further analyzed using Auger emission depth profiling, which confirmed the presence of Ge, Sb and Te in the film and further showed that Ge, Sb and Te atomic compositions were fairly uniform with some fluctuation in the depth direction. This result confirms the formation of a ternary composition throughout the thin film, rather than multiple binary or single element regions, layers or domains.

### EXAMPLE 4

In this example, a single layer two-element (GeTe) solid phase chalcogenide thin film is deposited by chemical vapor deposition. The deposition was performed on a SiN substrate that was rotated at 75 rpm. The CVD reactor, Te-precursor and Ge-precursor used in this example are as described in EXAMPLE 1, EXAMPLE 2 and EXAMPLE 3 hereinabove.

The deposition in this example was accomplished through a reaction of the Te-precursor and the Ge-precursor, where both precursors were present simultaneously in the CVD reactor. The precursors were introduced into the CVD reactor through separate feed lines. Helium (He) was used as a carrier gas for both precursors. The Te-precursor was placed in a bubbler heated to 75° C. and delivered to the CVD reactor through separate feed lines, also heated to 75° C. He was bubbled through the Te-precursor bubbler at a flow rate of 100 sccm to produce a gas stream containing the Te-precursor in a vapor phase form diluted in He, which serves as a carrier gas. This gas stream was further diluted in another 50 sccm of He and then introduced into the CVD reactor to provide the Te-precursor in a vapor phase form to the film formation reaction. The Ge-precursor was placed in a separate bubbler. 100 sccm of He was bubbled through the Ge-precursor bubbler to provide a gas stream containing the Ge-precursor in a vapor phase form in He as a carrier gas. This gas stream was further diluted with 150 sccm of He and then injected into the CVD reactor to provide the Ge-precursor in a vapor phase form to the film formation reaction.

During the deposition, 500 sccm of N₂ was delivered from the showerhead from above the substrate and 250 sccm of N₂ was delivered from below the substrate through the backfill line. The substrate was heated to 400° C. during the CVD reaction. The reaction was permitted to run for ˜15 minutes and on conclusion of the reaction, a film with an estimated thickness of about 1000-2000 Å had been formed on the substrate.

A scanning electron microscopy analysis of the film was completed and showed several larger crystallites in the presence of a finer grain background material. Elemental analysis of the background material and crystallites were completed using EDS. The EDS results indicated that the ratio of Ge:Te in the background material was approximately 1:1, thus indicating a stoichiometric GeTe composition. The EDS results indicated that the ratio of Ge:Te in the crystallites was also approximately 1:1, thus indicating a stoichiometric GeTe composition.

The film was further analyzed using Auger emission depth profiling. The Auger analysis confirmed the presence of Ge and Te in the film and further showed that the Ge and Te atomic compositions were uniform in the depth direction. This result confirms the formation of a binary GeTe composition throughout the thin film.

The instant invention extends generally to the chemical vapor deposition of chalcogenide thin films exhibiting electrical switching, accumulation, setting, resetting and/or memory functionality as described hereinabove. In one embodiment, the deposition occurs on a stationary substrate. In another embodiment, the deposition occurs on a moving substrate, such as a continuous web substrate, discrete substrates positioned on a moving conveyor or other transported substrates. The latter embodiment provides for the continuous deposition of a chalcogenide material according to the chemical vapor deposition process of the instant invention. The deposition chamber in the embodiment which includes a moving substrate includes a substrate inlet port into which the substrate is fed. The deposition chamber further includes means for delivering deposition precursors and the rate of delivery of deposition precursors and rate of transportation of the moving substrate are optimized to insure adequate residence time of the substrate in the growth environment of the chamber to insure deposition of a chalcogenide thin film. The deposition chamber further includes a substrate outlet port out of which the substrate, now containing the deposited thin film, is withdrawn. Deposition onto a moving substrate can occur through the formation of a multilayer structure as described in EXAMPLE 2 hereinabove or through the simultaneous introduction of multiple deposition precursors to form a single layer, multielement chalcogenide thin film as described in EXAMPLE 3 and EXAMPLE 4 hereinabove. The scope of this embodiment includes deposition onto a substrate that is continuously in motion during deposition as well as deposition onto substrates that are stationary during deposition, but which are transported sequentially into the deposition chamber for deposition in, for example, a “start-stop” or intermittent motion mode of operation in which substrate motion is interrupted during deposition and resumed upon completion of the deposition.

The examples described hereinabove demonstrate the use of isobutylgermane as a precursor for forming Ge layers or layers of Ge alloys, alone or in multilayer structures. Further embodiments of the instant invention extend to use of isobutylgermane and other Ge precursors within the scope of the instant invention to the formation of multilayer structures that include layers of Ge along with layers of Si or Si alloys. In a preferred embodiment, the multilayer structure includes a layer of Ge and a layer of Si. In another preferred embodiment, the multilayer structure includes a layer of Ge and a layer of SiGe. In another preferred embodiment, the multilayer structure includes a layer of SiGe and a layer of Si. Other preferred embodiments include multilayer structures having two or more layers of SiGe, where different ratios of Si:Ge are included in the layers. These embodiments further include multilayer structures that include a layer of Ge or a layer of Si.

The multilayer structures may be formed in a deposition process in which isobutylgermane is introduced into a deposition chamber and decomposed to form a solid film of Ge or containing Ge. Si layers can be formed by providing silane as a deposition precursor and decomposing.

Stacks including alternating Si and Ge layers are within the scope of the instant invention. Layers that include alloys of Si and Ge can be formed by providing isobutylgermane and silane simultaneously to a deposition chamber during deposition. By controlling the relative amounts of silane and isobutylgermane, SiGe alloys having varying proportions of Si and Ge can be formed.

The foregoing discussion and description are not meant to be limitations upon the practice of the present invention, but rather illustrative thereof. It is to be appreciated by persons of skill in the art that numerous equivalents of the illustrative embodiments disclosed herein exist. It is the following claims, including all equivalents and obvious variations thereof, in combination with the foregoing disclosure which define the scope of the invention.

1. A method for forming a multilayer structure comprising the steps of:
Providing a substrate;
Placing said substrate in a deposition chamber;
Delivering one or more deposition precursors to said deposition chamber, said deposition precursors being delivered in vapor phase form, at least one of said deposition precursors comprising isobutylgermane; said deposition precursors reacting to form a solid phase thin film on said substrate, said solid phase thin film comprising Ge.

2. The method of claim 1, wherein said one or more deposition precursors further includes silane.

3. The method of claim 2, wherein said solid phase thin film comprises an alloy of Si and Ge.

4. A method for forming a multilayer structure comprising the steps of:
Providing a substrate;
Placing said substrate in a deposition chamber;
Delivering a first deposition precursor to said deposition chamber, said first deposition precursor comprising isobutylgermane, said first deposition precursor reacting to form a first solid phase thin film on said substrate, said first solid phase thin film comprising Ge;
Delivering a second deposition precursor to said deposition chamber, said second deposition precursor comprising silane, said second deposition precursor reacting to form a second solid phase thin film on said substrate, said second solid phase thin film comprising Si.

5. The method of 4, wherein said second deposition precursor further comprises isobutylgermane.

6. The method of claim 5, wherein said second solid phase thin film comprises an alloy of Si and Ge.

7. The method of claim 4, wherein said first deposition precursor further comprises silane.

8. The method of claim 7, wherein said first solid phase thin film comprises an alloy of Si and Ge.

9. The method of claim 8, wherein said second decomposition precursor further comprises isobutylgermane.

10. The method of claim 9, wherein said second solid phase thin film comprises an alloy of Si and Ge.

11. The method of claim 10, wherein said first and second solid phase thin films have different proportions of Si and Ge.

12. A method for forming a multilayer structure comprising the steps of:
Providing a substrate;
Placing said substrate in a deposition chamber;
Delivering a first deposition precursor to said deposition chamber, said first deposition precursor comprising silane, said first deposition precursor reacting to form a first solid phase thin film on said substrate, said first solid phase thin film comprising Si;
Delivering a second deposition precursor to said deposition chamber, said second deposition precursor comprising isobutylgermane, said second deposition precursor reacting to form a second solid phase thin film on said substrate, said second solid phase thin film comprising Ge.
